(19) United States
(12) Patent Application Publication
(10) Pub. No.: US 2024/0145636 A1
(43) Pub. Date: May 2, 2024

(54) LIGHT EMITTING ELEMENT, MANUFACTURING METHOD OF LIGHT EMITTING ELEMENT, AND DISPLAY DEVICE

(71) Applicant: Samsung Display Co., LTD., Yongin-si (KR)

(72) Inventors: Sang Ho PARK, Yongin-si (KR); Sang Ho JEON, Yongin-si (KR); Sung Hoon KIM, Yongin-si (KR)

(21) Appl. No.: 18/499,136

(22) Filed: Oct. 31, 2023

(30) Foreign Application Priority Data
Nov. 1, 2022 (KR) 10-2022-0143936

(51) Int. Cl. H01L 33/44; H01L 27/15; H01L 33/00; H01L 33/24; H01L 33/32

(52) U.S. Cl. CPC H01L 33/44; H01L 27/156; H01L 33/0075; H01L 33/24; H01L 33/32; H01L 2933/0025

(57) ABSTRACT

One or more embodiments of the disclosure provides a light-emitting element including an N-type semiconductor layer, a P-type semiconductor layer, an active layer between the N-type semiconductor layer and the P-type semiconductor layer, and an insulating layer on a semiconductor stacked structure including the N-type semiconductor layer, the P-type semiconductor layer, and the active layer, and including a first insulating structure and a second insulating structure, the first insulating structure being between the semiconductor stacked structure and the second insulating structure and including a metal oxide including two or more metal elements.

### CROSS-REFERENCE TO RELATED APPLICATION

This application claims priority to, and the benefit of, Korean Patent Application No. 10-2022-0143936 filed in the Korean Intellectual Property Office on Nov. 1, 2022, the entire contents of which are incorporated herein by reference.

### BACKGROUND

### 1. Field

The disclosure relates to a light-emitting element, a manufacturing method of a light-emitting element, and a display device.

### 2. Description of the Related Art

As information technology has developed, importance of a display device, which is a connection medium between a user and information, has been highlighted. The display device includes a light-emitting element configured to emit light.

The light-emitting element may be a diode that includes a P-type semiconductor, an N-type semiconductor, and a quantum well structure located therebetween. To manufacture a high-performance display device, it may be suitable to reduce a size of the light-emitting elements and to further improve luminous efficiency of the light-emitting element.

### SUMMARY

An aspect of the disclosure is to provide a light-emitting element having improved light-emitting efficiency and improved element characteristics, a manufacturing method of the light-emitting element, and a display device.

One or more embodiments of the disclosure provide a light-emitting element including an N-type semiconductor layer, a P-type semiconductor layer, an active layer between the N-type semiconductor layer and the P-type semiconductor layer, and an insulating layer on a semiconductor stacked structure including the N-type semiconductor layer, the P-type semiconductor layer, and the active layer, and including a first insulating structure and a second insulating structure, the first insulating structure being between the semiconductor stacked structure and the second insulating structure and including a metal oxide including two or more metal elements.

The two or more metal elements may include a first metal element, wherein at least a portion of the semiconductor stacked structure includes a base element, and wherein a bond-dissociation energy of an oxide of the first metal element is greater than a bond-dissociation energy of an oxide of the base element.

The base element may be gallium, wherein the N-type semiconductor layer includes an N-type gallium nitride, wherein the P-type semiconductor layer includes a P-type gallium nitride, and wherein a bond-dissociation energy of an oxide of the first metal element is greater than about 200 kJ/mol.

The first metal element may include one or more of Ta, Hf, Zr, La, Si, Ti, or Al.

The two or more metal elements may include a first metal element, wherein at least a portion of the semiconductor stacked structure includes a base element, and wherein an ionic radius of the first metal element in an oxide of the first metal element is greater than an ionic radius of the base element in an oxide of the base element.

The base element may include gallium, wherein the N-type semiconductor layer includes an N-type gallium nitride, wherein the P-type semiconductor layer includes a P-type gallium nitride, and wherein an ionic radius of the first metal element in the oxide of the first metal element is greater than 0.62 Å.

The two or more metal elements may include a first metal element, wherein the N-type semiconductor layer includes an N-type gallium nitride, wherein the P-type semiconductor layer includes a P-type gallium nitride, and wherein the first metal element includes one or more of Zn, Ta, Hf, Zr, or La.

The first insulating structure may be directly adjacent to the semiconductor stacked structure, and may include a first insulating layer including an oxide including the first metal element.

The first insulating structure may further include an additional insulating layer between the first insulating layer and the second insulating structure, and including a base insulating layer, and an interface insulating layer between the first insulating layer and the base insulating layer.

The interface insulating layer may include a composite metal oxide including the first metal element.

The interface insulating layer and the base insulating layer may include a same second metal element, wherein a bond-dissociation energy of an oxide of the second metal element is greater than a bond-dissociation energy of an oxide of the base element.

The first insulating structure may include first to n-th insulating layers (n being an odd number greater than or equal to 3) that include a metal oxide, that include an (m−1)-th insulating layer including an interface insulating layer, and that include an m-th insulating layer including a most-adjacent insulating layer or a base insulating layer (m being an odd number of 3 or more, and less than or equal to n), wherein the (m−1)-th insulating layer includes a metal oxide including a first metal element of an (m−2)-th insulating layer, and a second metal element of the m-th insulating layer.

The first insulating structure may include an amorphous structure or a single phase structure.

The two or more metal elements may include different concentration gradients in a direction from the semiconductor stacked structure toward the second insulating structure in the first insulating structure.

The two or more metal elements may include a first metal element and a second metal element, wherein, in the first insulating structure, a ratio of the first metal element to the second metal element increases in a direction toward the semiconductor stacked structure, and a ratio of the second metal element to the first metal element increases in a direction toward the second insulating structure.

At least a portion of the semiconductor stacked structure may include a base element, wherein an interface layer including a metal oxide including the base element is between the semiconductor stacked structure and the first insulating structure.

The first insulating structure may be about 10 nm from the semiconductor stacked structure.

At least a portion of the semiconductor stacked structure may include one or more of a gallium-base material and a phosphide-base material.

One or more other embodiments of the disclosure provide a light-emitting element including an N-type semiconductor layer including an N-type gallium nitride, a P-type semiconductor layer including a P-type gallium nitride, an active layer between the N-type semiconductor layer and the P-type semiconductor layer, and an insulating layer covering at least a portion of each of the N-type semiconductor layer, the P-type semiconductor layer, and the active layer, and including a second insulating structure, and a first insulating structure that is adjacent to the N-type semiconductor layer, the P-type semiconductor layer, and the active layer compared to the second insulating structure, and that includes a metal oxide, wherein a bond-dissociation energy of the metal oxide is greater than a bond-dissociation energy of a gallium oxide, and wherein an ionic radius of a metal forming the metal oxide is greater than an ionic radius of gallium included in the gallium oxide.

One or more other embodiments of the disclosure provide a manufacturing method of a light-emitting element, the method including forming a base semiconductor stacked structure including an N-type base semiconductor layer, a P-type base semiconductor layer, and a base active layer on a growth substrate, providing a semiconductor stacked pattern by patterning the base semiconductor stacked structure, and forming an insulating layer including a first insulating structure, and a second insulating structure on the first insulating structure, on the semiconductor stacked pattern, the first insulating structure including a composite metal oxide layer including a metal oxide including two or more metal elements.

The semiconductor stacked pattern may include a semiconductor stacked structure including an N-type semiconductor layer, an P-type semiconductor layer, and an active layer, wherein the forming of the first insulating structure includes forming base layers on the semiconductor stacked structure.

At least a portion of the semiconductor stacked structure may include a base element, wherein the two or more metal elements include a first metal element, wherein the forming of the first insulating structure includes forming an interface layer including an oxide including the base element between the semiconductor stacked structure and the first insulating structure, wherein a bond-dissociation energy of an oxide of the first metal element is greater than a bond-dissociation energy of an oxide of the base element, and wherein an ionic radius of the first metal element in the oxide of the first metal element is greater than an ionic radius of the base element in an oxide of the base element.

The first insulating structure may be formed in a process environment of a first temperature, wherein the second insulating structure is formed in a process environment of a second temperature that is greater than the first temperature.

A difference between the second temperature and the first temperature may be about 50° C. to about 250° C.

The base layers may include a first base layer including a metal oxide including a metal of M1, and a second base layer including a metal oxide including a metal of M2, wherein the forming of the second insulating structure includes forming a first insulating layer including a metal oxide including M1, forming a second insulating layer including a metal oxide including M1 and M2, and forming a third insulating layer including a metal oxide including M2.

The base layers may include n base layers, wherein the forming of the second insulating structure includes forming 2n−1 insulating layers of the first insulating structure.

The base layers may include a first base layer including a metal oxide including a metal of M1, and a second base layer including a metal oxide including a metal of M2, wherein the forming of the second insulating structure includes providing the first insulating structure as the composite metal oxide layer including M1 and M2.

The forming of the second insulating structure may include providing the base layers as a single layer.

A display device according to an embodiment of the disclosure may include the light emitting element.

According to one or more embodiments of the disclosure, it is possible to provide a light-emitting element having improved light-emitting efficiency and improved element characteristics, a manufacturing method of the light-emitting element, and a display device.

### BRIEF DESCRIPTION OF THE DRAWINGS

FIG. 1 illustrates a schematic cross-sectional view of a light-emitting element according to one or more embodiments.

FIG. 2 illustrates a schematic perspective view of a light-emitting element according to one or more embodiments.

FIG. 3 and FIG. 4 schematically illustrate an insulating layer of a light-emitting element according to one or more embodiments.

FIG. 5 illustrates a schematic flowchart of a manufacturing method of a light-emitting element according to one or more embodiments.

FIG. 6 illustrates a schematic flowchart of an operation of forming an insulating film according to one or more embodiments.

FIG. 7 illustrates a graph of process temperatures according to process operations according to one or more embodiments.

FIG. 8 to FIG. 14 schematically illustrate cross-sectional views of respective process operations for a manufacturing method of a light-emitting element according to one or more embodiments.

FIG. 15 illustrates a schematic top plan view of a display device including a light-emitting element according to one or more embodiments.

FIG. 16 and FIG. 17 illustrate cross-sectional views of a display device according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” and “at least one of A or B” may include A, B, or A and B. As used herein, “or” generally means “and/or,” and the term “and/or” includes any and all combinations of one or more of the associated listed items. For example, the expression, such as “A and/or B” may include A, B, or A and B. Similarly, expressions, such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The disclosure relates to a light-emitting element, a manufacturing method of the light-emitting element, and a display device. Hereinafter, a light-emitting element, a manufacturing method of the light-emitting element, and a display device according to one or more embodiments will be described with reference to the accompanying drawings.

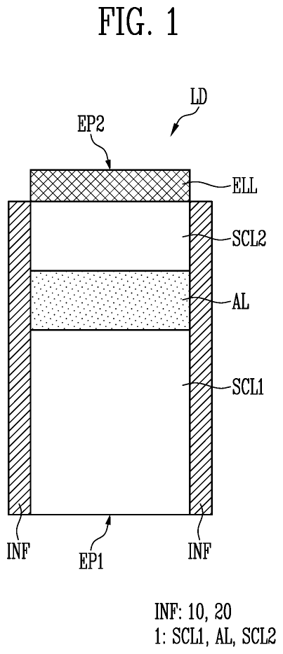

First, a light-emitting element LD according to one or more embodiments will be described with reference to FIG. 1 to FIG. 4.

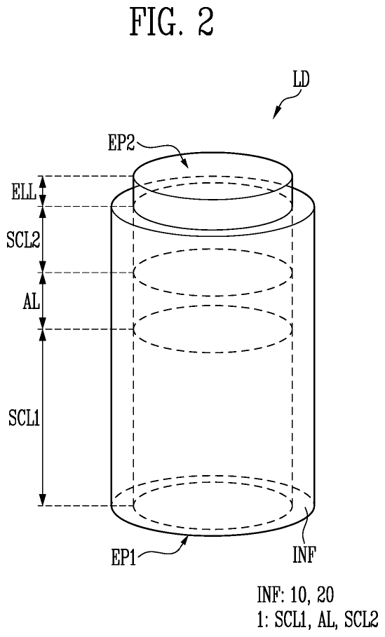

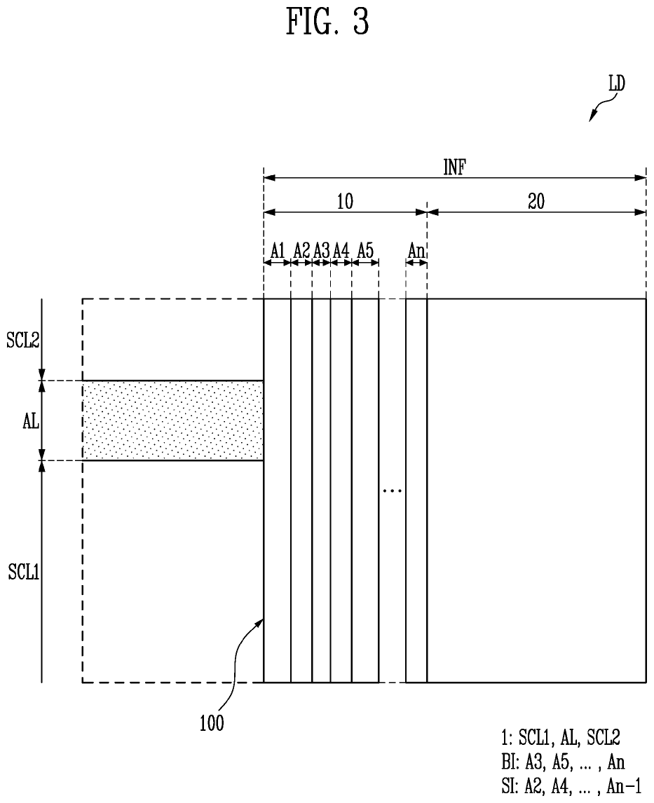

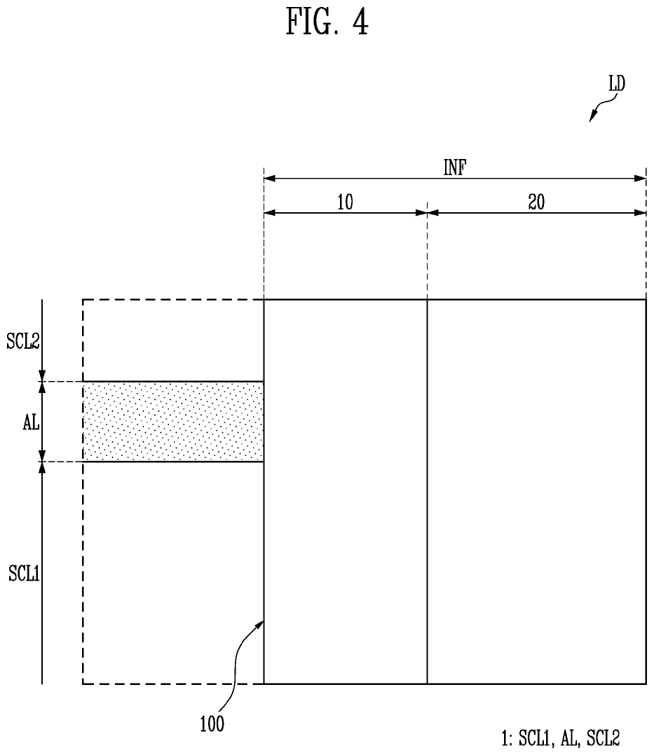

FIG. 1 illustrates a schematic cross-sectional view of a light-emitting element according to one or more embodiments. FIG. 2 illustrates a schematic perspective view of a light-emitting element according to one or more embodiments. FIG. 3 and FIG. 4 schematically illustrate an insulating layer of a light-emitting element according to one or more embodiments. FIG. 3 illustrates a schematic cross-sectional view of an insulating layer INF (or referred to as “insulating film”) according to one or more embodiments. FIG. 4 illustrates a schematic cross-sectional view of an insulating layer INF according to one or more other embodiments.

The light-emitting element LD is configured to emit light. In some embodiments, the light-emitting element LD may be a first light-emitting element configured to emit first light. The light-emitting element LD may be a second light-emitting element configured to emit second light. The light-emitting element LD may be a third light-emitting element configured to emit third light.

The first light may be light of a blue wavelength band, the second light may be light of a green wavelength band, and the third light may be light of a red wavelength band. The red wavelength band is a wavelength band of about 600 nm to about 750 nm, the green wavelength band is a wavelength band of about 480 nm to about 560 nm, and the blue wavelength band may be a wavelength band of about 370 nm to about 460 nm, but the disclosure is not necessarily limited thereto.

The light-emitting element LD includes an N-type semiconductor layer SCL1, a P-type semiconductor layer SCL2, an active layer AL located between the N-type semiconductor layer SCL1 and the P-type semiconductor layer SCL2, and the insulating layer INF. The light-emitting element LD may further include an electrode layer ELL on the P-type semiconductor layer SCL2.

The light-emitting element LD may have various sizes. In some embodiments, the light-emitting element LD may have a size of micro scale to nano scale. For example, a diameter of the light-emitting element LD may be about 100 μm or less. Alternatively, in some embodiments, the diameter of the light-emitting element LD may be about 1 μm or less. Here, a standard for the diameter of the light-emitting element LD may be determined according to a cross-sectional shape of the light-emitting element LD (for example, the active layer AL). For example, when the cross-section of the light-emitting element LD has a circular shape, the diameter thereof may be a diameter of the circular shape. When the cross-section of the light-emitting element LD has an elliptical shape, the diameter thereof may be a length of a long side of the elliptical shape. When the cross-section of the light-emitting element LD is a polygonal shape, the diameter thereof may be a longest diagonal length of the polygonal shape.

An etching process (for example, a dry etching process) for manufacturing the light-emitting element LD may affect luminous efficiency and the like of the light-emitting element LD. For example, there may be a risk that a lateral portion of the light-emitting element LD is damaged, and that the active layer AL is damaged, and in this case, the luminous efficiency of the light-emitting element LD may be deteriorated (for example, a decrease in luminous efficiency due to an increase in non-radiative recombination).

This risk may further increase as the light-emitting element LD is down-sized. For example, when the size of the light-emitting element LD is sufficiently large (for example, the size of the light-emitting element LD is about 100 μm or more), the luminous efficiency may be high in the order of luminous efficiency for red light, luminous efficiency for blue light, and luminous efficiency for green light, while, as the size thereof decreases, the luminous efficiency for red light and blue light may decrease, so that it may be suitable to correspondingly improve the luminous efficiency. However, the light-emitting element LD includes the insulating layer INF including a first insulating structure 10 and a second insulating structure 20, so that the aforementioned risk may be reduced or prevented, and the light-emitting element LD may be further down-sized. Hereinafter, features of the insulating layer INF will be described later.

The light-emitting element LD may have a first end portion EP1 and a second end portion EP2. In some embodiments, the N-type semiconductor layer SCL1 may be adjacent to the first end portion EP1 of the light-emitting element LD, and the P-type semiconductor layer SCL2 may be adjacent to the second end portion EP2 of the light-emitting element LD.

The N-type semiconductor layer SCL1 is located on the active layer AL, and may include a semiconductor layer of a type that is different from that of the P-type semiconductor layer SCL2. For example, the N-type semiconductor layer SCL1 may include an N-type semiconductor. For example, the N-type semiconductor layer SCL1 may include one or more of InAIGaN, GaN, AlGaN, InGaN, AlN, InP, and InN, and may include an N-type semiconductor layer doped with a first conductivity-type dopant, such as Si, Ge, and Sn. However, the disclosure is not limited to the above-described examples. The N-type semiconductor layer SCL1 may include various materials. For example, the N-type semiconductor layer SCL1 may have a structure implemented as an N-type semiconductor by including oxygen vacancies without including a dopant.

The active layer AL may be located between the N-type semiconductor layer SCL1 and the P-type semiconductor layer SCL2. The active layer AL may include a single-quantum well or multi-quantum well structure. The position of the active layer AL is not limited to a specific example, and may be variously changed according to a type of the light-emitting element LD.

The active layer AL may include a well layer and a barrier layer for forming a quantum well structure. In some embodiments, the active layer AL may include InGaN as a well layer, and the active layer AL may include GaN as a barrier layer. However, the disclosure is not necessarily limited thereto.

The P-type semiconductor layer SCL2 is located on the active layer AL, and may include a semiconductor layer of a type different from that of the N-type semiconductor layer SCL1. For example, the P-type semiconductor layer SCL2 may include a P-type semiconductor. For example, the P-type semiconductor layer SCL2 may include one or more semiconductor materials of InAIGaN, GaN, AlGaN, InGaN, AlN, InP, and InN, and may include a P-type semiconductor layer doped with a second conductivity-type dopant, such as Ca, Ba, and Mg. However, the disclosure is not limited to the above-described examples. The P-type semiconductor layer SCL2 may include various materials.

The electrode layer ELL may be located on the P-type semiconductor layer SCL2. The electrode layer ELL may be adjacent to the second end portion EP2. The electrode layer ELL may be an ohmic electrode, and a portion of the electrode layer ELL may be exposed. In some embodiments, the electrode layer ELL may include one or more of chromium (Cr), titanium (Ti), aluminum (Al), gold (Au), nickel (Ni), and an oxide thereof and an alloy thereof. However, the disclosure is not necessarily limited to the example described above.

In some embodiments, the structure of the light-emitting element LD is not limited to the above example, and may further include additional layer(s). For example, the light-emitting element LD may further include an electron-blocking layer to reduce or prevent overflow of electrons, and the light-emitting element LD may further include a superlattice layer for reducing stress in the light-emitting element LD.

When a voltage equal to or greater than a threshold voltage is applied to the first end portion EP1 and the second end portion EP2 of the light-emitting element LD, electron-hole pairs in the active layer AL may recombine with each other, and the light-emitting element LD may emit light. By controlling the light emission of the light-emitting element LD by using this principle, the light-emitting element LD may be used as a light source in various devices.

The insulating layer INF may surround a lateral portion of the light-emitting element LD. The insulating layer INF may be located on the semiconductor stacked structure 1 including the N-type semiconductor layer SCL1, the active layer AL, and the P-type semiconductor layer SCL2. For example, the insulating layer INF may cover at least a portion of each of the N-type semiconductor layer SCL1, the active layer AL, and the P-type semiconductor layer SCL2. The insulating layer INF may be patterned to surround the lateral portion of the light-emitting element LD to protect the light-emitting element LD from external influences and to insulate the N-type semiconductor layer SCL1, the active layer AL, and the P-type semiconductor layer SCL2.

The insulating layer INF may include a plurality of structures. For example, the insulating layer INF may include the first insulating structure 10 and the second insulating structure 20.

The first insulating structure 10 may be located between the semiconductor stacked structure 1 and the second insulating structure 20. The first insulating structure 10 may not be exposed from the lateral portion of the light-emitting element LD. The second insulating structure 20 may form an outer surface of the light-emitting element LD. The second insulating structure 20 may be located outside the first insulating structure 10.

The first insulating structure 10 may be more adjacent to the semiconductor stacked structure 1 than the second insulating structure 20. The first insulating structure 10 and the second insulating structure 20 may contact each other. The first insulating structure 10 may contact at least a portion of each of the N-type semiconductor layer SCL1, the P-type semiconductor layer SCL2, and the active layer AL. In some embodiments, the first insulating structure 10 may include a structure formed within about 10 nm from the semiconductor stacked structure 1.

The first insulating structure 10 may include one or more of metal elements of Groups 3 to 15, and rare earth metal elements. The first insulating structure 10 may include an oxide layer including a first metal element. A structure of the metal oxide based on the first metal element may be at least located at a position directly adjacent to an interface layer 100 of the first insulating structure 10. The first metal element may be selected based on physical characteristics of a base element for forming at least a portion of the semiconductor stacked structure 1.

The first metal element may be referred to as a metal element (e.g., a predetermined metal element). The first metal element may be a corresponding metal element.

A material including the base element may mean a material forming one or more of the N-type semiconductor layer SCL1, the active layer AL, and the P-type semiconductor layer SCL2. The base element is a material that forms one or more of the N-type semiconductor layer SCL1, the active layer AL, and the P-type semiconductor layer SCL2, and may mean an element that forms a material other than a dopant.

For example, when the N-type semiconductor layer SCL1 includes n-GaN, the base element may be gallium. When the P-type semiconductor layer SCL2 includes p-GaN, the base element may be gallium. When the active layer AL includes a gallium-base material, the base element may be gallium. However, the disclosure is not necessarily limited thereto. In some embodiments, when one or more of the N-type semiconductor layer SCL1, the P-type semiconductor layer SCL2, and the active layer AL include a phosphide-base material (for example, InP), the base element may be phosphorus (P).

For example, the example in which the base element forms at least a portion of the semiconductor stacked structure 1 may encompass an example in which a material based on the base element forms the N-type semiconductor layer SCL1, an example in which a material based on the base element forms the P-type semiconductor layer SCL2, an example in which a material based on the base element forms the active layer AL, or two or more of the foregoing examples.

The bond-dissociation energy of the oxide formed by the first metal element may be greater than the bond-dissociation energy of a compound formed by the base element for forming the semiconductor stack structure 1. Here, the semiconductor stacked structure 1 may refer to one or more of the N-type semiconductor layer SCL1, the active layer AL, and the P-type semiconductor layer SCL2, or may refer to the N-type semiconductor layer SCL1, the active layer AL, and the P-type semiconductor layer SCL2 as a whole.

When the bond-dissociation energy of the material forming the first insulating structure 10 is greater than the bond-dissociation energy of the material forming the semiconductor stacked structure 1, the influence on the semiconductor stacked structure 1 may be reduced or minimized, and the insulating film INF may be more stably formed. Therefore, the risk of damage to the light-emitting efficiency of the light-emitting element LD due to the insulating film INF may be reduced or prevented.

When the base element is gallium and the N-type semiconductor layer SCL1 and the P-type semiconductor layer SCL2 include a gallium nitride, to satisfy the condition of the bond-dissociation energy, the bond-dissociation energy of the oxide of the first metal element may be greater than about 200 kJ/mol. For example, the first metal element may be one or more of Ta, Hf, Zr, La, Si, Ti, and Al.

For example, the bond-dissociation energy of a gallium nitride may be about 200 kJ/mol. The bond-dissociation energy of a silicon oxide (SiₓO_{y}) may be about 799.6 kJ/mol. The bond-dissociation energy of an aluminum oxide (AlₓO_{y}) may be about 501.9 kJ/mol. The bond-dissociation energy of a titanium oxide (TiₓO_{y}) may be about 666.5 kJ/mol. The bond-dissociation energy of a tantalum oxide (TaₓO_{y}) may be about 839 kJ/mol. The bond-dissociation energy of a hafnium oxide (HfₓO_{y}) may be about 762 kJ/mol. The bond-dissociation energy of a zirconium oxide (ZrₓO_{y}) may be about 766.1 kJ/mol. The bond-dissociation energy of a lanthanum oxide (LaₓO_{y}) may be about 798 kJ/mol. Accordingly, when the first metal element is selected from the above-described examples and when the N-type semiconductor layer SCL1 and the P-type semiconductor layer SCL2 are the gallium nitride, the condition of the bond-dissociation energy is satisfied, so that the stability of the insulating film INF may be improved.

In some embodiments, when the bond-dissociation energy of the material forming the first insulating structure 10 is greater than the bond-dissociation energy of the material forming the interface layer 100, the influence on the semiconductor stacked structure 1 may be reduced or minimized, and the insulating film INF may be more stably formed.

When the base element is gallium and when the interface layer 100 includes a gallium oxide, to satisfy the condition of the bond-dissociation energy, the bond-dissociation energy of the oxide of the first metal element may be greater than about 545 kJ/mol. For example, the first metal element may be one or more of Ta, Hf, Zr, La, Si, and Ti. For example, the bond-dissociation energy of the oxide of each element may be as described above, and the bond-dissociation energy of the gallium oxide may be about 545 kJ/mol. Accordingly, when the first metal element is selected from the above-described examples and when the interface layer 100 includes the gallium oxide, the condition of the bond-dissociation energy is satisfied, so that the stability of the insulating film INF may be improved.

An ionic radius of the first metal element in the oxide formed by the first metal element may be greater than an ionic radius of the base element in the oxide formed by the base element.

For example, the interface layer 100 may be formed between the semiconductor stacked structure 1 and the first insulating structure 10. The interface layer 100 may mean a boundary area between the N-type semiconductor layer SCL1, the active layer AL, and the P-type semiconductor layer SCL2 and the first insulating structure 10.

Because the first insulating structure 10 includes an oxide, an oxide of the base element may be formed on the interface layer 100. For example, when the N-type semiconductor layer SCL1 and/or the P-type semiconductor layer SCL2 include a gallium based material (e.g., gallium nitride), a gallium oxide may be formed on the interface layer 100 based on the oxide of the first insulating structure 10 and a gallium of the N-type semiconductor layer SCL1 and/or the P-type semiconductor layer SCL2.

The ionic radius of the first metal element in the oxide formed by the first metal element may be larger than the ionic radius of the base element in the oxide formed by the base element, and in this case, it may be difficult for the first metal element to pass through the interface layer 100 and penetrate into the N-type semiconductor layer SCL1, the active layer AL, or the P-type semiconductor layer SCL2.

When an unintended metal material penetrates into the light-emitting element LD, stress may occur due to lattice mismatch between the penetrating metal material and the semiconductor stacked structure 1 inside the light-emitting element LD. However, as described above, because the ionic radius of the first metal element is selected according to a specific reference, it is difficult to penetrate into the semiconductor stacked structure 1 of the light-emitting element LD, so the above-described risk may be substantially eliminated.

When the base element is gallium (for example, when the N-type semiconductor layer SCL1 and the P-type semiconductor layer SCL2 are a gallium nitride), the ionic radius of the first metal element may be greater than about 0.62 Å. For example, the first metal element may include one or more of Zn, Ta, Hf, Zr, and La.

For example, the ionic radius of gallium in a gallium oxide may be about 0.62 Å. The ionic radius of tantalum in a tantalum oxide may be about 0.64 Å. The ionic radius of hafnium in a hafnium oxide may be about 0.71 Å. The ionic radius of zirconium in a zirconium oxide may be about 0.78 Å. The ionic radius of lanthanum in a lanthanum oxide may be about 1.032 Å. The ionic radius of zinc in a zinc oxide may be about 0.74 Å to about 0.88 Å. Accordingly, when the first metal element is selected from the above-described examples and when the gallium oxide structure is formed on the interface layer 100, the condition of the ionic radius is satisfied, so that the risk of penetration of the metal material into the semiconductor stacked structure 1 may be reduced or prevented.

On the other hand, when the base element is gallium in the semiconductor stacked structure 1, the first metal element may include one or more of Ta, Hf, Zr, and La, and in this case, the first insulating structure 10 that satisfies both the condition of the bond-dissociation energy and the condition of the ionic radius described above may be provided.

In some embodiments, the layer including the first metal element may be located at various positions within the first insulating structure 10. Various technical features of the insulating layer INF including this will be described in conjunction with FIG. 3 and FIG. 4.

First, referring to FIG. 3, the first insulating structure 10 may include one or more insulating layers. The first insulating structure 10 may include n insulating layers (n is a natural number greater than or equal to 1). The first insulating structure 10 may include first to n-th insulating layers A1 to An.

A first insulating layer A1 may be located to be most adjacent to the semiconductor stacked structure 1 to form the interface layer 100. The first insulating layer A1 may be located between the semiconductor stacked structure 1 and a second insulating layer A2. The first insulating layer A1 may be referred to as a most adjacent insulating layer. The first insulating layer A1 may be adjacent to the semiconductor stacked structure 1 with the interface layer 100 interposed therebetween.

The first insulating layer A1 may include a metal oxide including the aforementioned first metal element. For example, the first insulating layer A1 may include one or more of a tantalum oxide, a hafnium oxide, a zirconium oxide, and a lanthanum oxide.

In some embodiments, when the base element for forming at least some of the semiconductor stacked structure 1 is gallium, the first metal element forming the first insulating layer A1 may be one or more of Ta, Hf, Zr, and La.

Because the bond-dissociation energy of the first metal elements in the oxide state is greater than that of the gallium oxide, the first insulating layer A1 may be stably formed. In addition, because the ionic radius of the first metal elements in the oxide state is greater than that of gallium in the gallium oxide, the risk of the first metal elements penetrating the inside of the interface layer 100 may be reduced or prevented.

Additional insulating layer(s) may be formed on the first insulating layer A1. For example, an interface insulating layer Sl and a base insulating layer Bl may be alternately located on the first insulating layer A1. The interface insulating layer Sl may mean an even numbered insulating layer among n insulating layers A1 to An (for example, A2, A4, . . . and (A(n−1)). The base insulating layer Bl may mean an odd-numbered insulating layer among n insulating layers A3 to An (for example, A3, A5, . . . and An). (wherein n is an odd number greater than or equal to 3).

The interface insulating layer Sl may be located between adjacent base insulating layers Bl. For example, one surface of the interface insulating layer Sl may contact the base insulating layer Bl formed at one side, and the other surface of the interface insulating layer Sl may contact the base insulating layer Bl formed at the other side. In some embodiments, at least a portion of the interface insulating layer Sl may be formed within about 10 nm from the semiconductor stacked structure 1.

The base insulating layer Bl may be located between adjacent interface insulating layers Sl. In some embodiments, the base insulating layer Bl closest to the second insulating structure 20 may be located between the interface insulating layer Sl closest to the second insulating structure 20 and the second insulating structure 20.

The interface insulating layer Sl may include a metal oxide. The base insulating layer Bl may include a metal oxide. In some embodiments, the metal element included in the metal oxide forming the interface insulating layer Sl or the base insulating layer Bl may include one or more of the metal elements satisfying the above-mentioned condition of the bond-dissociation energy. For example, the metal element included in the metal oxide forming the interface insulating layer Sl or the base insulating layer Bl may include one or more of Ta, Hf, Zr, La, Si, Ti, and Al.

The interface insulating layer Sl may include all of the metal(s) forming each of the adjacent base insulating layers Bl, and may include a metal oxide based on the included metals.

The interface insulating layer Sl may be a composite metal oxide layer. In some embodiments, the composite metal oxide layer may include a stacked structure (for example, a layer-by-layer formation structure) in which a first metal oxide layer including a first metal and a second metal oxide layer including a second metal different from the first metal are alternately formed. Alternatively, in some embodiments, the composite metal oxide layer may include a structure (for example, a mixed layer formation structure) in which the first metal oxide layer and the second metal oxide layer are alternately located, and a layer including both the first metal and the second metal is formed between the first metal oxide layer and the second metal oxide layer. Alternatively, in some embodiments, the composite metal oxide layer may include a metal oxide layer structure in which the first metal and the second metal are formed as a whole.

For example, when the base insulating layers Bl (or the first insulating layer A1, and the base insulating layer(s) Bl adjacent thereto) adjacent to each other each include metal oxides of different metals, the corresponding interface insulating layer Sl may include a composite metal oxide including two or more metals.

For example, the first insulating structure 10 may include first to n-th insulating layers A1 to An (n may be an odd number greater than or equal to 3). In this case, the first insulating layer A1 may form the closest insulating layer, an m-th insulating layer Am may form the base insulating layer Bl, and an (m−1)-th insulating layer Am−1 may form the interface insulating layer Sl (m is an odd number greater than or equal to 3, and may be less than or equal to n). In this case, the metal oxide forming the (m−1)-th insulating layer Am−1 may commonly include the metal element of the metal oxide included in an (m−2)-th insulating layer Am−2 and the metal element of the metal oxide included in the m-th insulating layer Am.

As the number of the layers configuring the insulating film surrounding the lateral portion of the light-emitting element LD increases, element characteristics, such as the luminous efficiency of the light-emitting element LD, may be improved, and reliability of element performance may be improved. However, when the number of the layers configuring the insulating film is increased, stress may occur due to lattice mismatch between respective layers and the semiconductor layers in the light-emitting element. Accordingly, it may be difficult to form an insulating film structure having a sufficient number of layers on the lateral portion of the conventional light-emitting element LD.

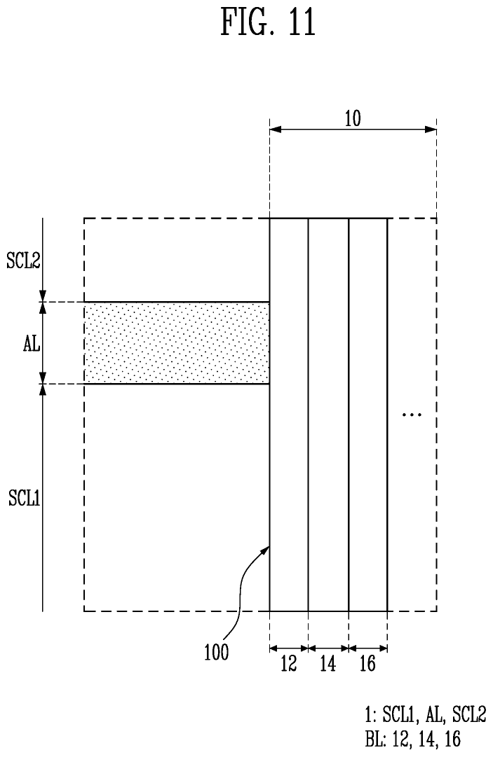

However, after forming a plurality of base layers BL (see FIG. 11), the plurality of base layers BL are manufactured to have a structure in which the interface insulating layer Sl is formed between the base insulating layers Bl under a first thermal environment. In this case, the effect of increasing the number of the layers forming the insulating film INF is provided without increasing the number of deposition processes of the layers forming the insulating film INF, and consequently, without risk occurring during the process of the light-emitting element LD, the element characteristics may be improved.

On the other hand, the examples of the metal element forming the first insulating structure 10 have been listed, but they are not particularly limited as long as the above conditions are satisfied.

Next, referring to FIG. 4, the first insulating structure 10 may include a single layer including a composite metal oxide. In some embodiments, two or more metals for forming the composite metal oxide may be included with a concentration gradient along a thickness direction within the first insulating structure 10. For example, two or more metals for forming the composite metal oxide may be formed with different concentration gradients in a direction from the semiconductor stacked structure 1 toward the second insulating structure 20 within the first insulating structure 10. In some embodiments, a ratio of the first metal element may increase as it is closer to the semiconductor stacked structure 1 in the first insulating structure 10, while a ratio of an additional metal element (for example, the second metal element) other than the first metal element may increase as it is closer to the second insulating structure 20.

The first insulating structure 10 may be a composite metal oxide layer. For example, the first insulating structure 10 may have a structure in which the complex metal oxide is entirely distributed.

The composite metal oxide forming the first insulating structure 10 may include at least the first metal element described above. In this case, the first metal element may be selected from elements that satisfy both the condition of the bond-dissociation energy and the condition of the ionic radius described above.

For example, when the base element is gallium in the semiconductor stacked structure 1, the first metal element may include one or more of Ta, Hf, Zr, and La, and in this case, the first insulating structure 10 that satisfies both the condition of the bond-dissociation energy and the condition of the ionic radius described above may be provided.

Accordingly, the first insulating structure 10 may be a composite metal oxide including one or more of Ta, Hf, Zr, and La. In some embodiments, the composite metal oxide may further include the second metal element (for example, an additional metal element) in addition to the first metal element. Here, the second metal element may include one or more of the elements satisfying the condition of the bond-dissociation energy described above. For example, the second metal element may include one or more of Ta, Hf, Zr, La, Si, Ti, and Al so as to not overlap with the first metal element.

The first insulating structure 10 may be manufactured by forming a plurality of base layers BL, and by then mixing the plurality of base layers BL in a boundary area adjacent to each other under a second thermal environment.

For example, the plurality of base layers BL may be amorphized so that the distinction between respective base layers BL may be released, or the plurality of base layers BL may be mixed as a whole and provided as a single phase.

Meanwhile, the second insulating structure 20 may be located on the lateral portion of the first insulating structure 10. The second insulating structure 20 may form an outermost structure of the light-emitting element LD. For example, the second insulating structure 20 may be a structure formed after the first insulating structure 10.

The second insulating structure 20 may include one or more of insulating materials. For example, the second insulating structure 20 may include one or more of the metal oxides satisfying the condition of the bond-dissociation energy described above.

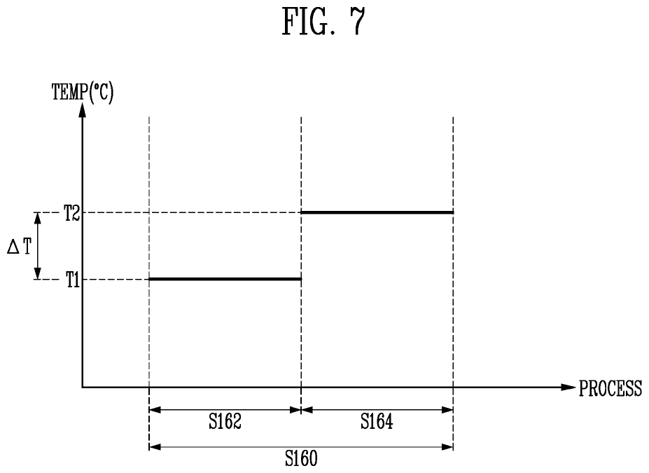

In some embodiments, the material for forming the second insulating structure 20 may form an amorphous structure at a process temperature (for example, a second temperature T2 (see FIG. 7)) that is greater than that of the material for forming the first insulating structure 10. In this case, the second insulating structure may be manufactured to have a crystal structure under a higher process temperature environment. To this end, the second insulating structure 20 may include one or more of Si, Ti, and Al. However, the disclosure is not necessarily limited thereto.

The second insulating structure 20 may have a greater thickness than the first insulating structure 10. Accordingly, the second insulating structure 20 may properly protect the semiconductor stacked structure 1 of the light-emitting element LD from external influences.

Meanwhile, the process temperature at which the second insulating structure is formed may change the structure of the first insulating structure 10 therebefore. This will be described in detail later.

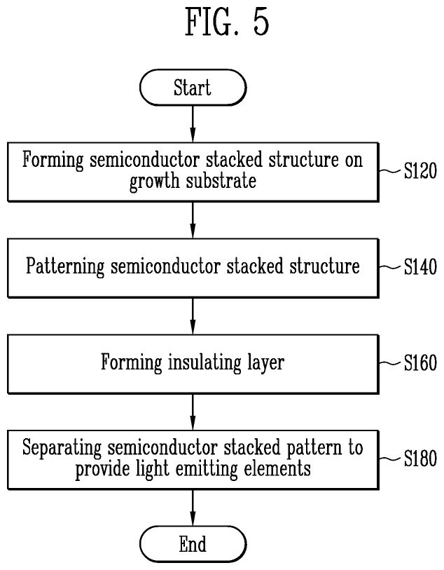

Hereinafter, a manufacturing method of a light-emitting element according to one or more embodiments will be described with reference to FIG. 5 to FIG. 14. Descriptions that may be redundant to those described above are simplified or are not repeated.

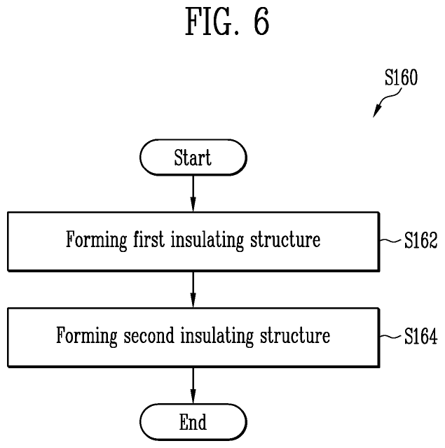

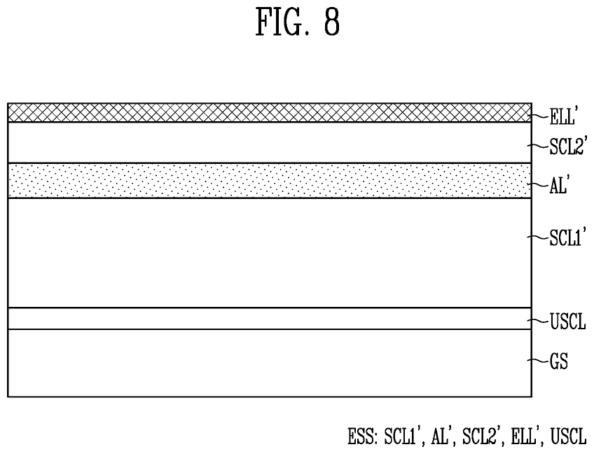

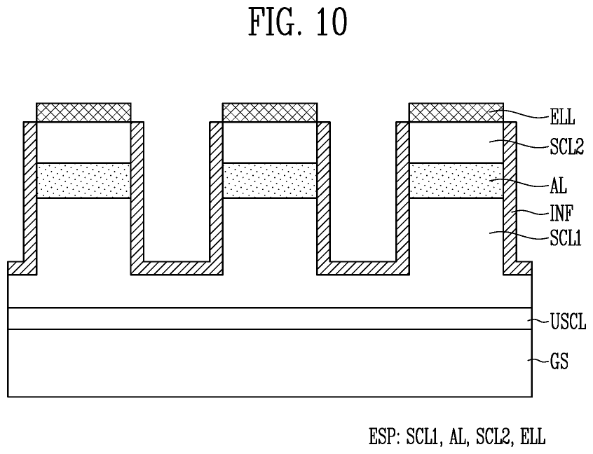

FIG. 5 illustrates a schematic flowchart of a manufacturing method of a light-emitting element according to one or more embodiments. FIG. 6 illustrates a schematic flowchart of an operation of forming an insulating film according to one or more embodiments. FIG. 7 illustrates a graph of process temperatures according to process operations according to one or more embodiments. FIG. 8 to FIG. 14 schematically illustrate cross-sectional views of respective process operations for a manufacturing method of a light-emitting element according to one or more embodiments. For example, FIG. 10 to FIG. 13 may be schematic cross-sectional views illustrating operations of forming the insulating layer INF.

Referring to FIG. 5, the manufacturing method of the light-emitting element may include forming a semiconductor stacked structure on a growth substrate (S120), patterning the semiconductor stacked structure (S140), forming an insulating layer (S160), and separating a semiconductor stacked pattern to provide light-emitting elements (S180).

Referring to FIG. 5 and FIG. 8, in the forming of the semiconductor stacked structure on the growth substrate (S120), a base semiconductor stacked structure ESS including an undoped semiconductor layer USCL, an N-type base semiconductor layer SCL1′, a first base active layer AL′, a P-type base semiconductor layer SCL2 ‘ and a base electrode layer ELL’ may be formed on a growth substrate GS.

The growth substrate GS may be a base plate for growing a target material. For example, the growth substrate GS may be a wafer for epitaxial growth of one material. The growth substrate GS may be a GaAs, GaP, or InP substrate, but the material for forming the growth substrate GS is not limited to a particular example.

The undoped semiconductor layer USCL may be located on a buffer layer (not shown) to reduce defects in semiconductor layers formed on the growth substrate GS. In some embodiments, the undoped semiconductor layer USCL may include GaN that does not include a separate dopant, but a material for forming the undoped semiconductor layer USCL is not limited to a particular example.

In some embodiments, a buffer layer for improving crystallinity of the semiconductor layer on the growth substrate GS may be formed between the growth substrate GS and the undoped semiconductor layer USCL.

The N-type base semiconductor layer SCL1′ may be epitaxially grown on the undoped semiconductor layer USCL. The N-type base semiconductor layer SCL1′ may include one or more of the aforementioned N-type semiconductor materials.

The base active layer AL′ may be epitaxially grown on the N-type base semiconductor layer SCL1′. In some embodiments, the base active layer AL′ may be formed as one of the above-described active layer structures.

The P-type base semiconductor layer SCL2′ may be epitaxially grown on the base active layer AL′. The P-type base semiconductor layer SCL2′ may include one or more of the aforementioned P-type semiconductor materials.

The base electrode layer ELL′ may be formed on the P-type base semiconductor layer SCL2′ based on a sputtering process or the like. However, the disclosure is not necessarily limited thereto. The base electrode layer ELL′ may include one or more of the materials for forming the electrode layer ELL described above.

To epitaxially grow the semiconductors of the base semiconductor stacked structure ESS, a process temperature may be set to one epitaxial process temperature. The epitaxial process temperature may have a temperature range suitable for epitaxially growing the base semiconductor stacked structure ESS. The epitaxial process temperatures may be about 300° C. to about 750° C. However, the disclosure is not necessarily limited thereto.

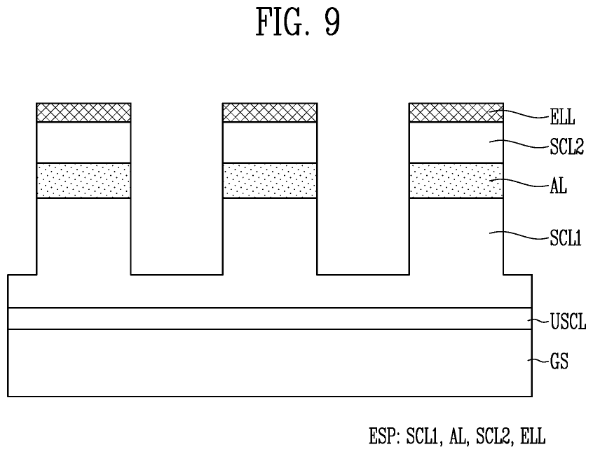

Referring to FIG. 5 and FIG. 9, in the patterning of the semiconductor stacked structure (S140), at least a portion of the base semiconductor stacked structure ESS may be etched to manufacture a semiconductor stacked pattern ESP.

The base semiconductor stacked structure ESS may be patterned by removing at least a portion of the base semiconductor stacked structure ESS to form the semiconductor stacked pattern ESP. For example, at least a portion of the base semiconductor stack structure ESS may be patterned through a dry etching process. In some embodiments, the base semiconductor stacked structure ESS may be etched along a thickness direction of the growth substrate GS.

In the dry etching process, a dry etching method, such as reactive ion etching (IE), reactive ion-beam etching (RIBE), or inductively coupled plasma reactive ion etching (ICP-RIE) may be used. However, the etching method is not necessarily limited to a particular example.

After the semiconductor stack pattern ESP is formed, the forming of the insulating layer (S160) may be performed. Referring to FIG. 6, the forming of the insulating layer (S160) may include forming a first insulating structure (S162) and forming a second insulating structure (S164).

Referring to FIG. 5 to FIG. 7, FIG. 10, and FIG. 11, in the forming of the first insulating structure (S162), the first insulating structure 10 may be patterned on the semiconductor stacked structure 1.

Hereinafter, the insulating layers formed on the semiconductor stacked structure 1 may be formed (or deposited) by various methods. For example, an atomic layer deposition (ALD) process or a chemical vapor deposition (CVD) process may be used. However, the disclosure is not necessarily limited thereto.

The base layers BL may be formed on the semiconductor stacked structure 1. For example, to form the base layers BL, a first base layer 12, a second base layer 14, and a third base layer 16 may be formed on the semiconductor stacked structure 1, and in some embodiments, additional base layers may be formed. In some embodiments, only the first base layer 12 may be formed on the semiconductor stacked structure 1. In some embodiments, only the first base layer 12 and the second base layer 14 may be formed on the semiconductor stacked structure 1.

The base layer BL may include the metal oxide including the metal element that satisfies the aforementioned bond-dissociation energy characteristic. Accordingly, the first insulating structure 10 may be stably formed on the semiconductor stacked structure 1.

The first base layer 12 may be directly adjacent to the semiconductor stacked structure 1 with the interface layer 100 interposed therebetween.

The first base layer 12 may include the metal oxide including the first metal element. For example, the first metal element included in the first base layer 12 may include one or more of the materials satisfying the above-described bond-dissociation energy characteristic and ionic radius characteristic.

In the present operation, because the metal oxide layer including the first metal element may be formed adjacent to the semiconductor stacked structure 1, a structure including an oxide of a base element of the semiconductor stacked structure 1 may be formed in the interface layer 100.

In this case, it may be difficult for the first metal element to penetrate the interface layer 100 due to the ionic radius characteristics of the first metal element of the first base layer 12. Accordingly, the stability of the semiconductor stacked structure 1 may be improved, and the penetration of impurities into the semiconductor stacked structure 1 may be reduced or prevented, thereby improving the luminous efficiency of the light-emitting element LD.

To form the first insulating structure 10 (for example, to form the base layer BL), the process temperature may be set to a first temperature T1 that is lower than a second temperature T2. The first temperature T1 may be set to a process temperature in a first formation temperature range. For example, the first temperature T1 may be determined based on a phase diagram of materials of adjacent base layers BL. For example, when a case in which the first base layer 12 includes a zirconium oxide, the second base layer 14 includes an aluminum oxide, and the third base layer 16 includes a zirconium oxide is described as a reference, in some embodiments, after the first base layer 12 is formed, the first base layer 12 may have a crystal structure at the first temperature T1. In addition, the second base layer 14 may have an amorphous structure under the same first temperature T1. The third base layer 16 may have a crystal structure under the first temperature T1. In this case, based on phase diagrams of a zirconium oxide and an aluminum oxide under first temperature T1, a solid-solution phase may be formed at the interface. That is, the first temperature T1, which is the process temperature for forming the first insulating structure 10, is appropriately selected based on the phase diagram of the materials forming the base layer BL, so that the interface phase may be properly implemented between the base layers BL.

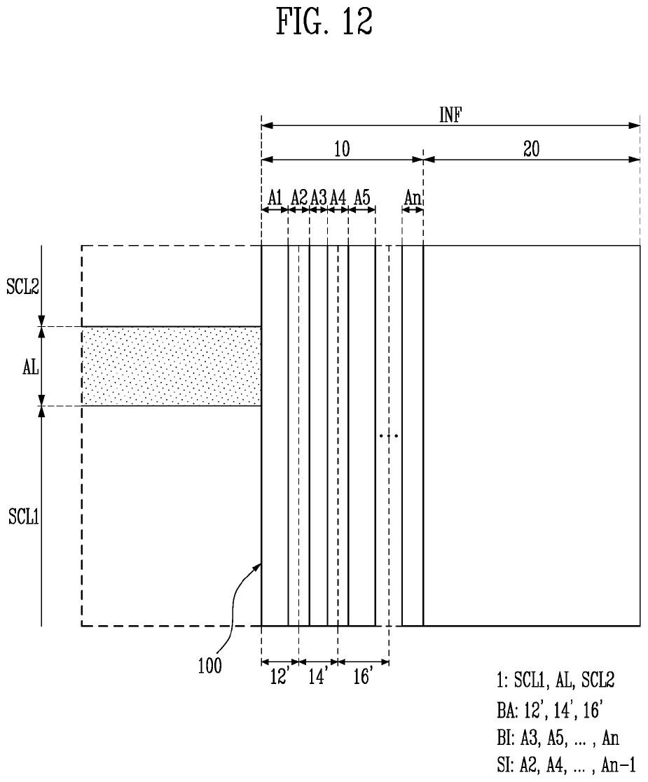

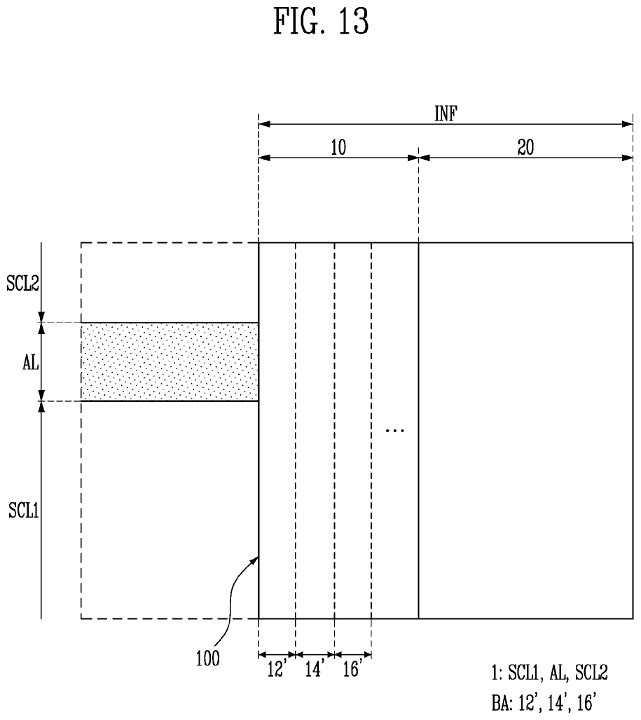

Referring to FIG. 5 to FIG. 7, FIG. 12, and FIG. 13, in the forming of the second insulating structure (S164), the second insulating structure 20 may be patterned on the first insulating structure 10.

In the present operation, the second insulating structure 20 may be formed outside the first insulating structure 10, so that the insulating layer INF may be provided on the outer surface of the light-emitting element LD.

Meanwhile, the structure of the first insulating structure 10 may be changed according to the process environment of the second insulating structure 20. For example, the structure of the base layer BL forming the first insulating structure 10 may be changed according to the second temperature T2, which is the process temperature of the second insulating structure 20. The second temperature T2 may be set to a process temperature in a second formation temperature range. Here, the second temperature T2 may be greater than the first temperature T1.

In some embodiments, as the second temperature T2 is determined, the degree of deformation of the first insulating structure 10 may be different. The second temperature T2 may be determined based on the phase diagram between the materials forming the first insulating structure 10. That is, the structure of the first insulating structure 10 may be controlled by adjusting the second temperature T2. As described above, because the second insulating structure 20 may form an amorphous structure only at a process temperature that is greater than that of the material for forming the first insulating structure 10, when a process is performed at the process temperature of the second temperature T2, the structure of the first insulating structure may be deformed, while the second insulating structure 20 may form an amorphous structure. For example, because the second insulating structure 20 includes a zirconium oxide, the zirconium oxide of the second insulating structure 20 may form a monoclinic crystal structure, and under the same process environment, the second insulating structure 20 may have an amorphous structure.

In some embodiments, a temperature change range ΔT, which is a difference between the second temperature T2 and the first temperature T1, may be about 50° C. to about 250° C. In some embodiments, the temperature change range ΔT may be about 50° C. to about 150° C. In some embodiments, the temperature change range ΔT may be about 80° C. to about 120° C. However, the disclosure is not necessarily limited thereto.

First, referring to FIG. 7 and FIG. 12, when the second temperature T2 is set to the first temperature range, the structures between adjacent base layers BL may be mixed, but the base layers BL in the first insulating structure 10 may not be mixed as a whole.

For example, when the second temperature T2 increases and the temperature change range ΔT is less than about 100° C., the structures between adjacent base layers BL may be mixed. In some embodiments, when the second temperature T2 increases and the temperature change range ΔT is less than about 95° C., the structures between adjacent base layers BL may be mixed. In some embodiments, when the second temperature T2 increases and the temperature change range ΔT is less than about 85° C., the structures between adjacent base layers BL may be mixed. However, the disclosure is not necessarily limited thereto. For example, the temperature change range ΔT may be selected according to the examples of the materials for forming the first insulating structure 10 and the second insulating structure 20.

The interface insulating layer Sl may be formed in an area between adjacent base layers BL. The base layer BL formed in each of base areas BA may form the base insulating layer(s) Bl (or the first insulating layer A1) and the interface insulating layer(s) SI adjacent thereto.

For example, the first base layer 12 formed in a first area 12′ may form at least a portion of each of the first insulating layer A1 and the second insulating layer A2. The second base layer 14 formed in a second area 14′ may form at least a portion of each of the second insulating layer A2, the third insulating layer A3, and the fourth insulating layer A4. The third base layer 16 formed in a third area 16′ may form at least a portion of the fourth insulating layer A4, the fifth insulating layer A5, and a sixth insulating layer.

For example, when the first base layer 12 in the first area 12′ includes a metal oxide including a metal element of M1 and the second base layer 14 in the second area 14′ includes a metal oxide including a metal element of M2, the first insulating layer A1 may include a metal oxide having a composition of M1ₓO_{y}, a second insulating layer A2 may include a metal oxide having a composition of M1ₓM2_{y}O_{z}, and the third insulating layer A3 may include a metal oxide having a composition of M2ₓO_{y}.

In this case, an additional number of insulating layers may be formed based on the number of the base layers BL formed the first insulating structure 10. For example, when n base layers BL are formed, the number of the manufactured first insulating layer A1 may be 1, the number of the manufactured base insulating layers Bl may be n−1, and the number of the manufactured interface insulating layers Sl may be n−1. Therefore, even while performing the process of forming n insulating layers, a technical effect similar to that of forming 2n−1 insulating layers may be derived. That is, as described above, because the number of the insulating layers A1 to An may be increased without increasing the number of separate deposition processes, structural stability of the light-emitting element LD may be secured.

Next, referring to FIG. 7 and FIG. 13, when the second temperature T2 is set to the second temperature range, the base layers BL may be mixed as a whole. In the present operation, the base layers BL may be provided as a single layer.

For example, when the second temperature T2 is increased and the temperature change range ΔT is about 100° C. or greater, the base layers BL may be mixed as a whole. In some embodiments, when the second temperature T2 is increased and the temperature change range ΔT is about 105° C., the base layers BL may be mixed as a whole. In some embodiments, when the second temperature T2 is increased and the temperature change range ΔT is about 130° C., the base layers BL may be mixed as a whole. However, the disclosure is not necessarily limited thereto. For example, the temperature change range ΔT may be selected according to the examples of the materials for forming the first insulating structure 10 and the second insulating structure 20.

The base layers BL may be amorphized or provided as a single phase at the process temperature of the second temperature T2 set to the second temperature range. In this case, a structure including the same materials may be entirely formed in the base area BA (for example, the first area 12′, the second area 14′, and the third area 16′).

In some embodiments, the composition of the metal oxide of the first insulating structure 10 may be defined according to the type of the metal oxide formed on each of the base layers BL. For example, when the first base layer 12 in the first area 12′ includes a metal oxide including a metal element of M1, when the second base layer 14 in the second area 14′ includes a metal oxide including a metal element of M2, and when the third base layer 16 in the third area 16′ includes a metal oxide including a metal element of M3, the first insulating structure 10 may have a composition of M1ₓM2_{y}M3_{z}O_{w}. Alternatively, in some embodiments, when the first base layer 12 in the first area 12′ includes a metal oxide including a metal element of M1 and when the second base layer 14 in the second area 14′ includes a metal oxide including a metal element of M2, the first insulating structure 10 may have a composition of M1ₓM2_{y}O_{z}. Alternatively, in some embodiments, when the first base layer 12 in the first area 12′ includes a metal oxide including a metal element of M1, when the second base layer 14 in the second area 14′ includes a metal oxide including a metal element of M2, and when the third base layer 16 in the third area 16′ includes a metal oxide including a metal element of M1, the first insulating structure 10 may have a composition of M1ₓM2_{y}O_{w}.

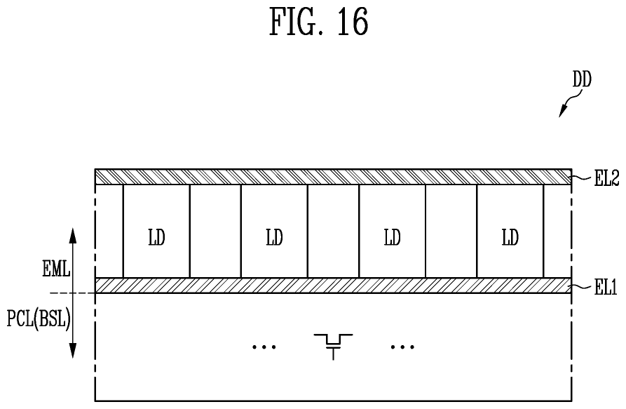

After the forming of the insulating layer (S160) is performed, an operation of providing light-emitting elements by separating the semiconductor stacked pattern (S180) may be performed. However, in some embodiments, the providing of the light-emitting elements (S180) is not performed, and after the semiconductor stacked pattern ESP is transferred onto a pixel circuit layer PCL (see FIG. 16), the growth substrate GS or the like may be removed to manufacture the light-emitting elements LD.

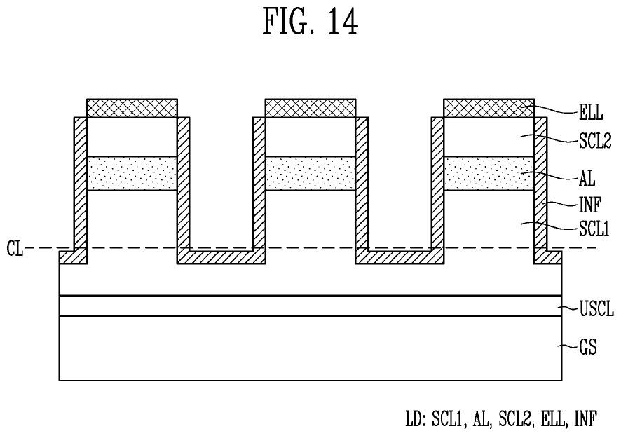

Referring to FIG. 14, in the present operation, a portion of the N-type semiconductor layer SCL1 may be cut along a cutting line CL. In some embodiments, a laser lift off (LLO) process may be performed to cut a portion of the N-type semiconductor layer SCL1. However, the disclosure is not necessarily limited thereto.

In some embodiments, in the present operation, the cutting line CL may correspond to each N-type semiconductor layer SCL1 of the individually separated semiconductor stacked pattern ESP. In this case, the light-emitting elements LD may be individually separated.

In some embodiments, the N-type semiconductor layers SCL1 of each of the light-emitting elements LD may not be separated by the cutting line CL. Accordingly, the light-emitting elements LD may share the structure of the N-type semiconductor layer SCL1 with each other.

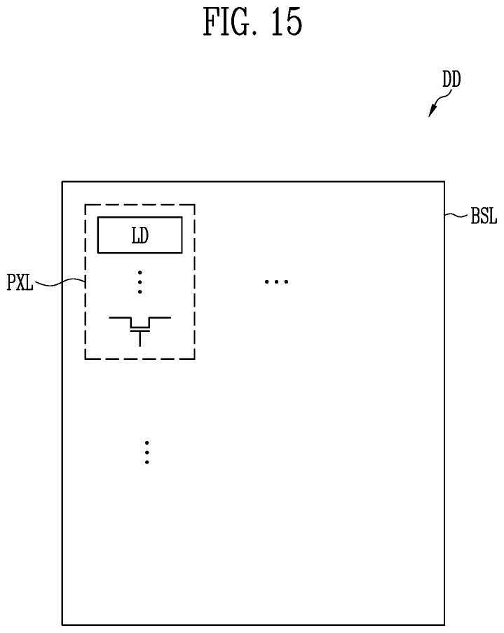

Then, in one or more embodiments, the manufactured light-emitting element LD may be transferred onto the pixel circuit layer PCL by using various methods, and accordingly, a display device DD according to one or more embodiments (see FIG. 15) may be manufactured.

Hereinafter, the display device DD including the light-emitting element LD will be described with reference to FIG. 15 to FIG. 17. Descriptions that may be redundant to those described above are simplified or are not repeated.

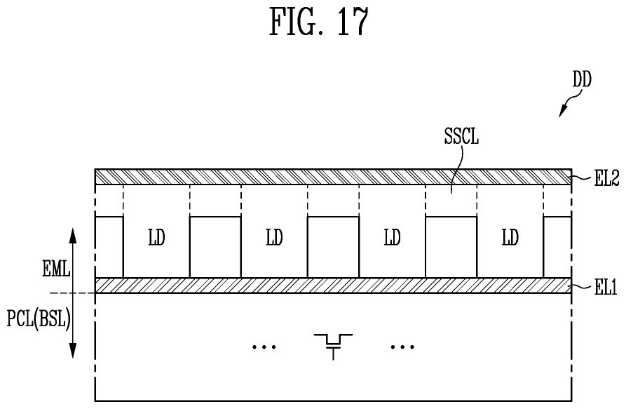

FIG. 15 illustrates a schematic top plan view of a display device including a light-emitting element according to one or more embodiments. FIG. 16 and FIG. 17 illustrate cross-sectional views of a display device according to one or more embodiments.

Referring to FIG. 15 to FIG. 17, the display device DD may include a base layer BSL, and pixels PXL formed on the base layer BSL.

The base layer BSL is a member forming a base surface on which the pixels PXL are located, and may be a substrate or a film. In some embodiments, the base layer BSL may be a rigid substrate of a glass material. Alternatively, the base layer BSL may be a flexible substrate that is bendable, foldable, or rollable. In this case, the substrate may include an insulating material, such as a polymer resin (e.g., a polyimide).

The pixels PXL may include the aforementioned light-emitting elements LD.

The display device DD may include the base layer BSL and the pixel circuit layer PCL including a driving circuit on the base layer BSL. In addition, the display device DD may include a light-emitting element layer EML that is located on the pixel circuit layer PCL and on which the light-emitting elements LD are located.

The light-emitting element layer EML may include a first electrode EL1 electrically connected to one end portion of the light-emitting element LD and a second electrode EL2 electrically connected to the other end portion of the light-emitting element LD.

The light-emitting elements LD may provide light based on electrical signals supplied by driving transistors of driving circuits (for example, electrical signals provided from the first electrode EL1 and the second electrode EL2). In some embodiments, the light-emitting elements LD may emit light of various colors, respectively, and the light-emitting elements LD that emit light of the same color may each form a sub-pixel, and the formed sub-pixels may form one or more pixels PXL (or pixel units). In some embodiments, the driving circuit may include a circuit structure including three transistors and one storage capacitor. However, the disclosure is not necessarily limited thereto. For example, the driving circuit may be implemented with various numbers of transistors and storage capacitors.

Meanwhile, in some embodiments, the light-emitting elements LD may be individually separated to be transferred onto the first electrode EL1 (FIG. 16). Alternatively, in some embodiments, the N-type semiconductor layer SCL1 of each of the light-emitting element LD may be integrally formed with a mutually shared semiconductor layer SSCL (FIG. 17).

As discussed above, because the light-emitting elements LD are manufactured to have reduced process risks and high luminous efficiency, the display device DD including the light-emitting element LD may be manufactured as a high-quality product. For example, the display device DD including the light-emitting element LD may be manufactured as a device having high resolution, and may be applied to a wearable device, a head-mounted device, and the like as a small-scale device. In addition, the display device DD may be applied to a future-oriented display system requiring high quality, such as augmented reality and virtual reality.

While the disclosure has been shown and described with reference to certain embodiments thereof, it will be understood by those skilled in the art that various changes in forms and details may be made therein without departing from the spirit and scope of the disclosure as defined by the appended claims and their equivalents. Therefore, the technical scope of the disclosure may be determined by on the technical scope of the accompanying claims, with functional equivalents thereof to be included therein.

What is claimed is:

1. A light-emitting element comprising:
an N-type semiconductor layer;
a P-type semiconductor layer;
an active layer between the N-type semiconductor layer and the P-type semiconductor layer; and
an insulating layer on a semiconductor stacked structure comprising the N-type semiconductor layer, the P-type semiconductor layer, and the active layer, and comprising a first insulating structure and a second insulating structure, the first insulating structure being between the semiconductor stacked structure and the second insulating structure and comprising a metal oxide comprising two or more metal elements.

2. The light-emitting element of claim 1, wherein the two or more metal elements comprise a first metal element,
wherein at least a portion of the semiconductor stacked structure comprises a base element, and
wherein a bond-dissociation energy of an oxide of the first metal element is greater than a bond-dissociation energy of an oxide of the base element.

3. The light-emitting element of claim 2, wherein the base element is gallium,
wherein the N-type semiconductor layer comprises an N-type gallium nitride,
wherein the P-type semiconductor layer comprises a P-type gallium nitride, and
wherein a bond-dissociation energy of an oxide of the first metal element is greater than about 200 kJ/mol.

4. The light-emitting element of claim 2, wherein the first metal element comprises one or more of Ta, Hf, Zr, La, Si, Ti, or Al.

5. The light-emitting element of claim 2, wherein the two or more metal elements comprise a first metal element,
wherein at least a portion of the semiconductor stacked structure comprises a base element, and
wherein an ionic radius of the first metal element in the oxide of the first metal element is greater than an ionic radius of the base element in an oxide of the base element.

6. The light-emitting element of claim 5, wherein the base element comprises gallium,
wherein the N-type semiconductor layer comprises an N-type gallium nitride,
wherein the P-type semiconductor layer comprises a P-type gallium nitride, and
wherein an ionic radius of the first metal element is greater than 0.62 Å.

7. The light-emitting element of claim 1, wherein the two or more metal elements comprise a first metal element,
wherein the N-type semiconductor layer comprises an N-type gallium nitride,
wherein the P-type semiconductor layer comprises a P-type gallium nitride, and
wherein the first metal element comprises one or more of Zn, Ta, Hf, Zr, or La.

8. The light-emitting element of claim 2, wherein the first insulating structure is directly adjacent to the semiconductor stacked structure, and comprises a first insulating layer comprising an oxide comprising the first metal element.

9. The light-emitting element of claim 8, wherein the first insulating structure further comprises an additional insulating layer between the first insulating layer and the second insulating structure, and comprising a base insulating layer, and an interface insulating layer between the first insulating layer and the base insulating layer.

10. The light-emitting element of claim 9, wherein the interface insulating layer comprises a composite metal oxide comprising the first metal element.

11. The light-emitting element of claim 9, wherein the interface insulating layer and the base insulating layer comprise a same second metal element, and
wherein a bond-dissociation energy of an oxide of the second metal element is greater than a bond-dissociation energy of an oxide of the base element.

12. The light-emitting element of claim 1, wherein the first insulating structure comprises first to n-th insulating layers (n being an odd number greater than or equal to 3) that comprise a metal oxide, that comprise an (m−1)-th insulating layer comprising an interface insulating layer, and that comprise an m-th insulating layer comprising a most-adjacent insulating layer or a base insulating layer (m being an odd number of 3 or more, and less than or equal to n), and
wherein the (m−1)-th insulating layer comprises a metal oxide comprising a first metal element of an (m−2)-th insulating layer, and a second metal element of the m-th insulating layer.

13. The light-emitting element of claim 1, wherein the first insulating structure comprises an amorphous structure or a single phase structure.

14. The light-emitting element of claim 13, wherein the two or more metal elements comprise different concentration gradients in a direction from the semiconductor stacked structure toward the second insulating structure in the first insulating structure.

15. The light-emitting element of claim 14, wherein the two or more metal elements comprise a first metal element and a second metal element, and
wherein, in the first insulating structure, a ratio of the first metal element to the second metal element increases in a direction toward the semiconductor stacked structure, and a ratio of the second metal element to the first metal element increases in a direction toward the second insulating structure.

16. The light-emitting element of claim 1, wherein at least a portion of the semiconductor stacked structure comprises a base element, and
wherein an interface layer comprising a metal oxide comprising the base element is between the semiconductor stacked structure and the first insulating structure.

17. The light-emitting element of claim 1, wherein the first insulating structure is about 10 nm from the semiconductor stacked structure.

18. The light-emitting element of claim 1, wherein at least a portion of the semiconductor stacked structure comprises one or more of a gallium-base material and a phosphide-base material.

19. A light-emitting element comprising:
an N-type semiconductor layer comprising an N-type gallium nitride;
a P-type semiconductor layer comprising a P-type gallium nitride;
an active layer between the N-type semiconductor layer and the P-type semiconductor layer; and
an insulating layer covering at least a portion of each of the N-type semiconductor layer, the P-type semiconductor layer, and the active layer, and comprising a second insulating structure, and a first insulating structure that is adjacent to the N-type semiconductor layer, the P-type semiconductor layer, and the active layer compared to the second insulating structure, and that comprises a metal oxide,
wherein a bond-dissociation energy of the metal oxide is greater than a bond-dissociation energy of a gallium oxide, and
wherein an ionic radius of a metal forming the metal oxide is greater than an ionic radius of gallium comprised in the gallium oxide.

20. A manufacturing method of a light-emitting element, the method comprising:
forming a base semiconductor stacked structure comprising an N-type base semiconductor layer, a P-type base semiconductor layer, and a base active layer on a growth substrate;
providing a semiconductor stacked pattern by patterning the base semiconductor stacked structure; and
forming an insulating layer comprising a first insulating structure, and a second insulating structure on the first insulating structure, on the semiconductor stacked pattern, the first insulating structure comprising a composite metal oxide layer comprising a metal oxide comprising two or more metal elements.

21. The manufacturing method of the light-emitting element of claim 20, wherein the semiconductor stacked pattern comprises a semiconductor stacked structure comprising an N-type semiconductor layer, an P-type semiconductor layer, and an active layer, and
wherein the forming of the first insulating structure comprises forming base layers on the semiconductor stacked structure.

22. The manufacturing method of the light-emitting element of claim 21, wherein at least a portion of the semiconductor stacked structure comprises a base element,
wherein the two or more metal elements comprise a first metal element,
wherein the forming of the first insulating structure comprises forming an interface layer comprising an oxide comprising the base element between the semiconductor stacked structure and the first insulating structure,
wherein a bond-dissociation energy of an oxide of the first metal element is greater than a bond-dissociation energy of an oxide of the base element, and
wherein an ionic radius of the first metal element in the oxide of the first metal element is greater than an ionic radius of the base element in an oxide of the base element.

23. The manufacturing method of the light-emitting element of claim 21, wherein the first insulating structure is formed in a process environment of a first temperature, and
wherein the second insulating structure is formed in a process environment of a second temperature that is greater than the first temperature.

24. The manufacturing method of the light-emitting element of claim 23, wherein a difference between the second temperature and the first temperature is about 50° C. to about 250° C.

25. The manufacturing method of the light-emitting element of claim 23, wherein the base layers comprise a first base layer comprising a metal oxide comprising a metal of M1, and a second base layer comprising a metal oxide comprising a metal of M2, and
wherein the forming of the second insulating structure comprises:
forming a first insulating layer comprising a metal oxide comprising M1;
forming a second insulating layer comprising a metal oxide comprising M1 and M2; and
forming a third insulating layer comprising a metal oxide comprising M2.

26. The manufacturing method of the light-emitting element of claim 23, wherein the base layers comprise n base layers, and
wherein the forming of the second insulating structure comprises forming 2n−1 insulating layers of the first insulating structure.

27. The manufacturing method of the light-emitting element of claim 23, wherein the base layers comprise a first base layer comprising a metal oxide comprising a metal of M1, and a second base layer comprising a metal oxide comprising a metal of M2, and
wherein the forming of the second insulating structure comprises providing the first insulating structure as the composite metal oxide layer comprising M1 and M2.

28. The manufacturing method of the light-emitting element of claim 23, wherein the forming of the second insulating structure comprises providing the base layers as a single layer.

29. A display device comprising the light-emitting element of claim 1.
